(19) United States
(12) Patent Application Publication
(10) Pub. No.: US 2006/0238070 A1
(43) Pub. Date: Oct. 26, 2006

(54) Electronic circuit comprising embedded piezoelectric transformer

(75) Inventors: Francois Costa, Cachan (FR); Dejan Vasic, Paris (FR); Emmanuel Sarraute, Champs Sur Marne (FR)

Correspondence Address: MILLER, MATTHIS & HULL, ONE NORTH FRANKLIN STREET, SUITE 2350, CHICAGO, IL, 60606, US

(73) Assignees: CENTRE NATIONAL DE LA RECHERCHE SCIENTIFIQUE-CNRS, Paris (FR); ECOLE NORMALE SUPERIEURE DE CACHAN, Cachan Cedex (FR)

(21) Appl. No.: 10/555,344

(22) PCT Filed: Apr. 29, 2004
(86) PCT No.: PCT/FR04/01041

§ 371 Date: Nov. 1, 2005

(30) Foreign Application Priority Data
May 7, 2003 (FR) 03/05601

(51) Int. Cl. H01L 41/107

(52) U.S. Cl. 310/318

(57) ABSTRACT

An electronic circuit provided with a piezoelectric transformer for driving an electronic component. The transformer is integrated in the circuit, a first layer of the circuit having a first primary piezoelectric plate integrated therein, a second layer having a secondary piezoelectric plate integrated therein and connected to the electronic component, and an intermediate layer comprising an insulating material is interposed between the primary and secondary plates.

The present invention relates to electronic circuits, in particular to electronic circuits for driving electronic power components.

More particularly, the invention relates to an electronic circuit provided with a piezoelectric transformer for driving an electronic component, in which circuit the transformer comprises a primary plate and a secondary plate made from a piezoelectric material, together with an intermediate insulating layer interposed between the primary and secondary plates, the primary plate being arranged to transmit a displacement signal to the secondary plate through the intermediate layer in response to a primary signal that is transmitted to the primary plate via the electronic circuit, and the secondary plate delivering a secondary signal to the electronic component as a function of the primary signal for the purpose of driving the electronic component to which the secondary plate is connected.

In the article entitled “Commande de transistor à grille isolée par transformateur piézo-électrique” [Driving an insulated-gate transistor via a piezoelectric transformer] Congrès EPF 2002, Montpellier, France, November 2002, the inventors propose using such an electronic circuit that comprises a multilayer piezoelectric transformer, in which the primary and secondary plates are each formed by a layer of piezoelectric material provided with its electrodes, so as to perform a close drive function of an insulated gate power transistor. In that circuit, the purpose of the transformer is to transmit drive instructions in a way that is very reliable and that provides excellent galvanic isolation.

A particular object of the present invention is to improve that type of circuit, in particular by proposing a concrete way of integrating the piezoelectric transformer in the electronic circuit that includes the electronic component to be controlled.

For this purpose, the invention provides an electronic circuit which, in addition to the above-specified characteristics, is characterized in that it comprises a first layer in which the primary plate is integrated and a second layer in which the secondary plate is integrated, the first and second layers being galvanically isolated from each other by the intermediate layer.

By means of these dispositions, the primary and secondary plates of the piezoelectric transformer are respectively in the first and second layers, which themselves may constitute, for example, respective primary and secondary electronic circuits of the transformer.

In preferred embodiments of the invention, recourse may optionally be had to one or more of the following dispositions:
the first and second layers are constituted by a substrate of a material selected from printed circuit material, ceramic material, and semiconductor material, and each supporting one printed circuit face, the primary and secondary plates being fastened in recesses previously formed in each of the layers respectively;
at least one conductive layer is interposed between the first and second layers;
the electronic component is a power transistor integrated in the second layer and having a gate receiving the secondary signal;
the first layer has a primary circuit comprising a modulator connected to the primary plate and adapted to form the primary signal with at least one carrier signal being modulated by a drive signal, and to deliver the primary signal as formed in this way to the primary plate; and the second layer has a secondary circuit comprising a demodulator connected between the secondary plate and the electronic component, and adapted to transmit to said electronic component a signal demodulated from the secondary signal corresponding to the drive signal (the carrier signal can be modulated by the drive signal using amplitude modulation or frequency modulation);
the secondary circuit further comprises a rectifier device connected between the secondary plate and the demodulator, and adapted to rectify the secondary signal delivered by the secondary plate;
the secondary circuit further comprises a locking device connected between the demodulator and the electronic component and adapted to deliver a reliable demodulated signal to the electronic component;
the electronic circuit comprises an oscillator adapted to deliver the carrier signal to the modulator at a frequency that is close to a mechanical resonant frequency of the transformer;
the oscillator is adapted to deliver a carrier signal at a frequency close to the frequency of the second resonant mode of vibration of the transformer;
the primary and secondary plates are made out of a piezoelectric material that is biased in thickness;
the electronic component is a MOSFET or an IGBT; and
the electronic circuit further comprises an additional piezoelectric primary plate integrated in the first layer, and an additional piezoelectric secondary plate integrated in the second layer and connected to an additional electronic component, the electronic component being connected to form a complete arm of a bridge.

Other characteristics and advantages of the invention appear from the following description of an embodiment thereof, given by way of non-limiting example and with reference to the accompanying drawings.

In the drawings:

FIG. 1 is a diagrammatic section showing an example of a drive printed electronic circuit in accordance with the invention and having a piezoelectric transformer integrated therein;

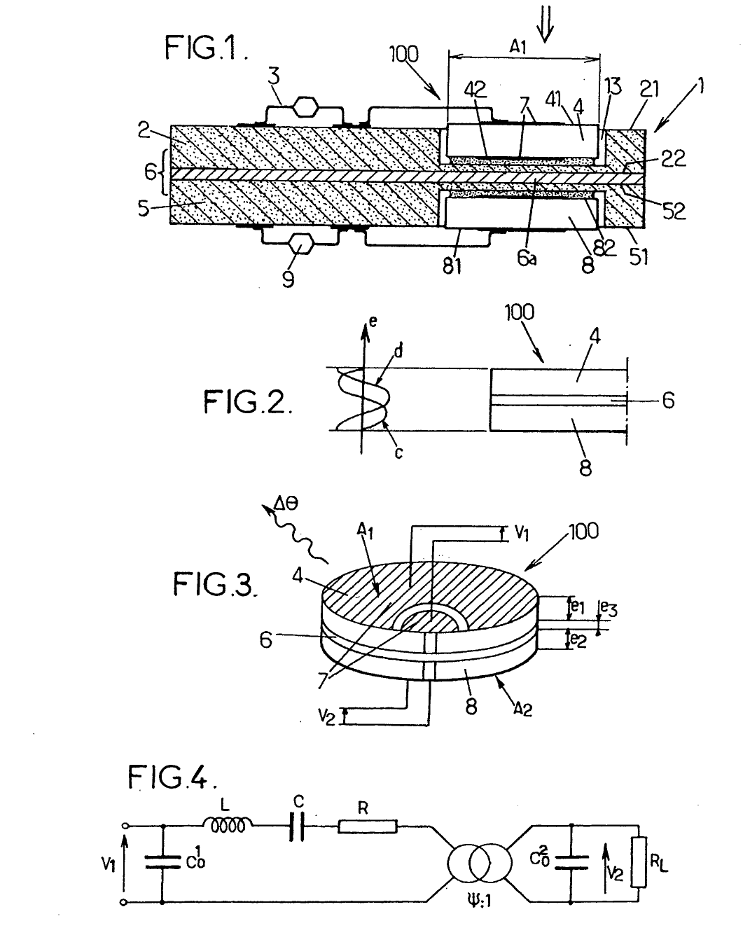

FIG. 2 is a diagrammatic view showing the thickness vibration mode of the piezoelectric transformer of the FIG. 1 electronic circuit;

FIG. 3 is a diagrammatic perspective view of a piezoelectric transformer, such as that integrated in the FIG. 1 circuit;

FIG. 4 is a simplified electrical circuit diagram of the transformer shown in FIG. 3;

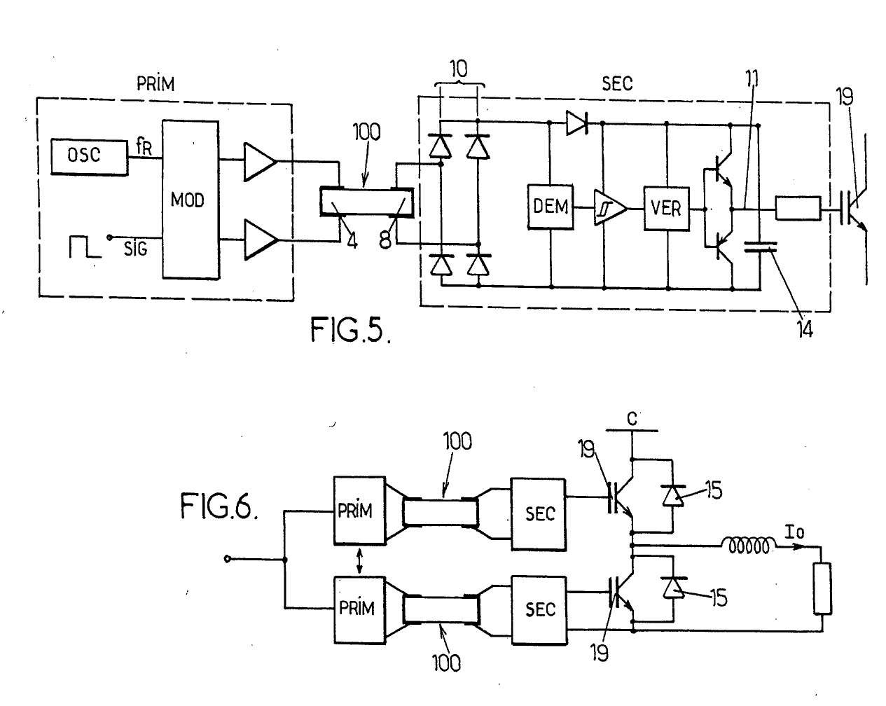

FIG. 5 is the electrical circuit diagram of the FIG. 1 circuit; and

FIG. 6 is another example of a drive circuit of the invention for applying close drive to a transistor gate.

In the various figures, elements that are identical or similar are designated by the same references.

FIG. 1 is an example of an electronic circuit 1 of the invention. In this example, there is a printed circuit 1, e.g. based on an insulating substrate made of epoxy, alumina, etc. It has a first layer 2, and a second layer 5. The first and second layers 2 and 5 each carry one of the faces of the printed circuit that faces outwards. A primary electronic circuit is made on one of the faces 21 and a secondary electronic circuit is made on the other face 51. These two circuits, the primary circuit and the secondary circuit, are electrically insulated from each other by an intermediate layer 6 constituted by a greater or lesser thickness of the material constituting the primary and secondary layers 2 and 5.

In addition, in the embodiment shown herein, a conductive layer 6a is inserted between the primary and secondary layers 2 and 5. This conductive layer 6a provides an electrostatic screen between the first and second layers 2 and 5.

The primary and secondary circuits carry one or more primary and second electronic components 3 and 9.

The primary and secondary layers 2 and 5 are of thickness lying in the range about 0.5 mm to 2 mm. Each of the first and second layers 2 and 5 presents a preformed recess 13 in which a primary or a secondary plate 4 or 8 is secured.

The primary and secondary plates 4 and 8 are made, for example, out of lead zircono-titanate (PZT), being generally plane and circular or rectangular in shape, e.g. having respective areas A₁ and A₂ and thicknesses e₁, e₂ close to the thicknesses of the first layer 2 and of the second layer 5, respectively.

The respective areas A₁ and A₂ of the primary and secondary plates 4 and 8 are substantially equal. However the respective thicknesses e₁ and e₂ of the primary and secondary plates 4 and 8 may be different.

The primary and secondary plates 4 and 8 possess respective inner faces 42 and 82 facing towards the other plate when the plates are in position in their respective recesses 13. Similarly, the primary and secondary plates 4 and 8 have outer faces 41 and 81 facing away from their inner faces 42 and 82 and lying substantially flush with the primary and secondary circuits respectively of the electronic circuit 1. The primary and secondary plates 4 and 8 are thus placed in such a manner that when viewed in a direction normal to the primary and secondary faces of the electronic circuit 1 (e.g. in the direction of the double-shafted arrow in FIG. 1), the primary and secondary plates 4 and 8 are substantially superposed.

The primary and secondary plates 4 and 8 are also covered over at least a fraction of each of their inner and outer faces 42, 82 and 41, 81 with metallization 7 enabling electrical contact to be made thereto.

The primary and secondary plates 4 and 8 can be fastened in their recesses 13 by co-sintering, for example, by placing a piezoelectric powder, the insulating layer, and the metallization in a mold for fabricating the circuit, and then applying pressure thereto.

Fastening may also be achieved by adhering the inner faces 42, 82 of the plates when they are made separately on the respective epoxy substrates of the first and second layers 2 and 5. It is preferable to use an adhesive having thermal and mechanical properties that are appropriate for this type of application, specifically, the ability to withstand temperature rises, great hardness, and good behavior when in tension. An epoxy adhesive could be used, for example. The plate is also biased so as to vibrate across its thickness when it is subjected to alternating electric current.

The primary and secondary plates 4 and 8 are spaced apart by about 0.1 millimeters (mm) to 1 mm. Between them there is the intermediate layer 6, with its embedded conductive layer 6a.

By way of example, the conductive layer can be constituted by copper or by any other material suitable for providing an electrostatic screen.

The primary and secondary plates 4 and 8 as integrated in this way in a printed circuit and as separated by an electrostatic screen constitute an integrated piezoelectric transformer 100.

The power transfer delivered by the transformer 100 takes place by initially transforming electrical energy in the primary plate 4 into mechanical vibration in the thickness of the primary plate 4. This mechanical vibration generates vibration in the material(s) interposed between the primary and secondary plates 4 and 8, and in the secondary plate 8. The vibration is recovered from the secondary plate 8 in the form of electrical energy. Consequently, there is no electromagnetic coupling in this type of transformer, and that is favorable in terms of standards relating to electromagnetic compatibility.

Such an integrated transformer 100 can be used to implement a function of applying close drive to a power transistor, such as a MOSFET, an IGBT, or any other power semiconductor, and to do so with excellent isolation.

By way of example, a transformer 100 is used in which the primary and secondary plates 4 and 8 are identical in material, in area, and in thickness, and are biased in the thickness direction, as shown diagrammatically on the right in FIG. 2.

The transformer 100 is excited at a frequency corresponding to its second mode of vibration. Variations are thus obtained in the stresses c and the displacement d along thickness as shown on the left-hand side of FIG. 2. With this second mode of vibration, stresses are small in the intermediate layer 6 to which the primary and secondary plates 4 and 8 are stuck, which is beneficial in terms of avoiding risks of unsticking. However, the intermediate layer 6 is subjected to maximum displacement.

The mode of vibration can be adapted to the shape of the transformer in thickness in order to satisfy this condition for low stresses in the region where adhesion occurs. This adaptation can be desirable, in particular when the primary and secondary plates 4 and 8 are of thicknesses e₁ and e₂ that are not identical. Nevertheless, it is not absolutely essential for this condition to be satisfied, for example if the adhesive is strong enough.

The technical characteristics and performance of such a transformer 100 are closely associated with the physical and mechanical characteristics of the type of material used, and with the dimensions of the elements constituting the transformer 100.

If one has a priori knowledge of the type of application for which the transformer 100 is likely to be used, it can be dimensioned accordingly.

As shown in FIG. 3, a voltage V₁ is applied to the primary plate 4 of the transformer 100 (shown in purely illustrative manner as being cylindrical), having dimensions e₁ and A₁, and a voltage V₂ is obtained from the secondary plate 8 having dimensions e₂ and A₂. Account may optionally be taken of the intermediate layer of thickness e₃ and area A₃ while dimensioning the transformer.

In operation under these conditions, the mechanical losses in the transformer 100 are converted into a dissipation of heat Δθ, and it can be advantageous to control this in order to ensure proper operation of the electronic circuit 1 as a whole. To achieve this, it is possible to apply the following modeling.

The electrical circuit diagram of FIG. 4 is used which is an equivalent circuit diagram for the transformer 100 in its resonant modes, as described in “Piezoelectric transformer operating in thickness extensional vibration and its application to switching converter”, PESC 94, Zaitsu et al. In this circuit, the inductance, resistance, and capacitance values L, R, C, C¹₀, and C²₀ are associated with the physical and mechanical characteristics of the transformer 100. The resistance R_{L} designates the resistance of the load on the transformer 100. To simplify, dimensioning details are given for a primary plate 4 and a secondary plate 8 made of identical materials, but these details can easily be transposed to primary and secondary plates 4 and 8 made of different materials.

Geometrically, each plate 4 or 8 is characterized by its thickness e₁, e₂ and by its area A₁, A₂. The material is physically characterized by its modulus of elasticity in its thickness c₃₃^{D}, by its permittivity ε₃₃^{s}, its piezoelectric coefficient e₃₃, its density ρ, its mechanical quality factor Qₘ, a coefficient for convection within the material h_{c}, and an electromechanical coupling coefficient kₜ.

In a Mason model, coupling between the geometrical and physical characteristics of each plate is represented by a perfect transformer of gain Ψ₁, Ψ₂ as expressed for example by:

$${Ψ}_{1} = \frac{{A}_{1}}{{e}_{1}} {e}_{33}$$

In the model shown, these two perfect transformers are grouped together as a single transformer with gain Ψ.

In such a transformer, the physical and mechanical characteristics can be associated with the electrical properties of the equivalent circuit of FIG. 4 by the following equations:
C¹₀=ε₃₃^{s}×A₁/e₁
C²₀=ε₃₃^{s}×A₂/e₂
L=(e₁+e₂+e₃)e₁²ρ/8A₁e²₃₃
C=A₁e²₃₃/π²e₁c₃₃^{D}
R=[1/Qₘ]×(L/C)^{1/2}
Ψ=A₁e₂/A₂e₁

Below, for purely illustrative purposes, a transformer is described having two plates with the same area A (A₁=A₂=A) and in which the thicknesses e₁ and e₂ are large compared with the thickness e₃ of the intermediate layer (e₁+e₂+e₃≈e₁+e₂), however the operations described below can perfectly well be performed for a general example.

In short-circuit, the transformer presents a resonant angular frequency ω_{S}=1/(LC)^{1/2}.

To take account of the charge state of the transformer, an electrical quality factor Q can be introduced that depends of the equivalent resistance of the load R_{L} of the circuit to which the power is to be transmitted:
Q=1/R_{L}C²₀ω_{S}

It is also possible to use a ratio c that represents the fraction of the mechanical energy that can be converted into electrical energy in the secondary:
c=Ψ²C²₀/C=(π²/2kₜ²)(e₂/(e₁+e₂))−(e₁+e₂)/e₂

The resonant angular frequency ω_{R} of the entire circuit can be estimated by taking account of the load resistance, using the following expression associating ω_{R}, c, and ω_{S}:

$$\frac{{ω}_{R}^{2}}{{ω}_{S}^{2}} = \frac{1}{2} ( 1 + \frac{1}{c} - {Q}^{2} ) + \sqrt{\frac{1}{4} {( 1 + \frac{1}{c} - {Q}^{2} )}^{2} + {Q}^{2}}$$

As a function of these various circuit parameters and of the voltage V₁ and of the operating frequency ω_{R}, the power transmitted P₂, the gain G, and the efficiency η of the transformer 100 can be expressed as follows:

$$\begin{matrix}G = \frac{{V}_{2}}{{V}_{1}} \\ = \frac{Ψ}{\sqrt{{[ 1 - c ( \frac{{ω}_{R}^{2}}{{ω}_{S}^{2}} - 1 + \frac{Q}{{Q}_{m}} ) ]}^{2} + {[ \frac{c}{{Q}_{m}} \frac{{ω}_{R}}{{ω}_{S}} + cQ ( \frac{{ω}_{R}}{{ω}_{S}} - \frac{{ω}_{S}}{{ω}_{R}} ) ]}^{2}}}\end{matrix}$$

$${P}_{2} = \frac{\frac{{V}_{1}^{2}}{R} c \frac{Q}{{Q}_{m}}}{{[ 1 - c ( \frac{{ω}_{R}^{2}}{{ω}_{S}^{2}} - 1 + \frac{Q}{{Q}_{m}} ) ]}^{2} + [ \frac{c}{{Q}_{m}} \frac{{ω}_{R}}{{ω}_{S}} + cQ ( \frac{{ω}_{R}}{{ω}_{S}} - \frac{{ω}_{S}}{{ω}_{R}} ) ]}$$

$$and$$

$$η = \frac{1}{1 + \frac{Q}{{Q}_{m}} c ( 1 + \frac{1}{{Q}^{2}} \frac{{ω}_{R}^{2}}{{ω}_{S}^{2}} )}$$

The various sources of losses lead to the structure becoming heated. Also, the properties of the piezoelectric material are sensitive to the surrounding temperature. It can therefore be desirable to dimension a transformer so that its temperature rise in operation is less than some predefined value Δθ. Since heating losses are written h_{c}SΔθ, where S is the area of heat exchange with the outside (S=2A=A₁+A₂ for a thin transformer), the temperature rise will not exceed Δθ providing the following condition is satisfied:
P₂ (1−η)/η<h_{c}SΔθ

Replacing η by the above expression gives:

$$1 - \frac{{h}_{c} S Δ θ}{{P}_{2}} \frac{{Q}_{m}}{c} \frac{1}{Q} + \frac{{ω}_{R}^{2}}{{ω}_{S}^{2}} \frac{1}{{Q}^{2}} < 0$$

which is a function of Q representing the influence of the circuit to be driven via the transformer.

When using such a system of equations, the choice of an operating point Q for the circuit makes it possible to determine the geometrical and physical properties of the transformer. By way of example, this operating point may be conditioned by requirements relating to the maximum volume of the transformer, optimum performance, e.g. in terms of gain, power transmission, efficiency, a compromise between these various requirements, etc. Two non-limiting examples are given below.

For example it is desired to make a transformer constituted by two plates of thicknesses e₁, e₂ and of area A, the transformer being biased to operate in its second thickness vibration mode. The transformer is fed with a power supply voltage V₁ at a power supply frequency f_{R}. The plates are made of a given material, having a coupling coefficient kₜ, permittivity 633, a mechanical quality factor Qₘ, density ρ, Young's modulus c₃₃, piezoelectric coefficient e₃₃, and convection coefficient h_{c}. The transformer needs to present gain G close to 1, and deliver power P₂ for a maximum temperature rise Δθ not to be exceeded.

The values of the thicknesses e₁ and e₂ are relatively close when using single-layer plates, since it is difficult for a thin layer to impart movement to a thick layer. Consequently, the gain of the transformer is close to 1. If gain much greater than 1 is desired, it can be preferable to use a multilayer structure in parallel for the secondary, and to adapt the above equations accordingly.

The total thickness eₜₒₜ is selected so that the power supply frequency f_{R} corresponds to the second mode of vibration of the transformer, thus making it possible, when using two similar plates, to minimize the stresses at the adhesively-bonded interfaces for optimum gain, as described above. The total thickness eₜₒₜ of the transformer can thus be selected to be about:
eₜₒₜ=e₁+e₂(+e₃)=2π/ω_{R}(c₃₃/ρ)^{1/2}

For the materials conventionally used to make the primary and secondary plates, e.g. for lead titanate (M5), the modulus of elasticity in thickness c₃₃ can be of the order of 176 gigapascals (GPa) and the density p can be about 7400 kilograms per cubic meter (kg/m³). For vibration at a frequency of about 2.1 megahertz (MHz), a total thickness of about 2.3 mm is obtained, which is compatible with the sizes of the printed circuits that are commonly used for power transistors. For integration purposes, the thickness can be further reduced by using a higher excitation frequency for the transformer. Nevertheless, a compromise is necessary since increasing the frequency leads to an increase in losses.

The other dimensions of the transformer (A, e₁, e₂) are now determined by selecting an operating point Q for the circuit. Two pertinent but non-exclusive selections are described below, however the transformer may equally well be dimensioned for any other type of operating point Q, in particular when there needs to be a compromise between the two examples described below.

In a first example, the power to be transmitted P₂ is known. This power comprises the power actually delivered to the power component 19, and any power that might possibly be delivered to any electronic components that might exist between the secondary plate 8 of the transformer 100 and the power component 19.

Two operating points Q₁ and Q₂ can be found constituted by the two roots of the temperature rise equation which is a second-degree polynomial in Q, between which the temperature rise in operation will be below the predefined temperature rise value Δθ. For these two points, the temperature rise of the transformer will be substantially equal to Δθ and the power delivered will be substantially equal to P₂. Either one of these two points can be used.

$$1 / {Q}_{1 , 2} = \frac{1}{2 {ω}_{R}^{2} / {ω}_{S}^{2}} \{ \frac{2 A}{c} \frac{{h}_{c} Δ θ {Q}_{m}}{{P}_{2}} \pm \sqrt{{( \frac{2 A {h}_{c} Δ θ {Q}_{m}}{{cP}_{2}} )}^{2} - 4 \frac{{ω}_{R}^{2}}{{ω}_{S}^{2}}} \}$$

In this first example, two possible dimensions are obtained for the transformer. It is then possible to select the dimensioning that appears to be the most appropriate, for example the dimensioning that minimizes the volume of the transformer.

In a second example, it may be desired to make an integrated piezoelectric transformer presenting given efficiency for a given temperature rise and given load resistance. An operating point Q₀ may be selected corresponding to optimum efficiency (with this operating point, corresponding to minimum losses, being situated between Q₁ and Q₂).
Q₀=\sqrt{1+½c}

In both examples, the area A of the primary and secondary plates and the ratio r=e₂/e₁ of the thickness of the plates can be determined to correspond to said temperature rise Δθ, to said operating point Q, and to said power that is to be transmitted, in particular by using the expressions for G and for P₂. For example, G and P₂ can be expressed as a function of A and the ratio r, with all of the other parameters being known and with the electrical quality factor likewise being expressed as a function of A and of r. The system of equations is solved in an appropriate manner, e.g. numerically or graphically. Finally, the thickness of each plate is obtained from r and from eₜₒₜ.

It is thus possible to dimension a piezoelectric transformer integrated in a printed circuit delivering power P₂ for a maximum allowable temperature rise Δθ. By using the values obtained for A and r in the various equations, it is possible to identify the various values of the components in the equivalent model, and in particular the acceptable load resistances R_{L} lying between the values R_{L1} and R_{L2} corresponding to Q₁ and Q₂. The operating performance of said transformer can also be predicted since the transmission efficiency η, the gain, and the power transmitted, amongst other things, are associated with the characteristics of the circuit and thus of the material.

For example, particular attention is given to a piezoelectric transformer made up of two similar plates made of lead titanate (M5), i.e. a primary plate and a secondary plate, having a coupling coefficient kₜ=0.5, permittivity ε₃₃=179ε₀ (where ε₀ is the permittivity of vacuum), mechanical quality factor Qₘ=400, piezoelectric coefficient e₃₃=8.5, and convection coefficient h_{c}=15 watts per kelvin per square meter (WK⁻¹m⁻²), the transformer being powered at a frequency f_{R}=2.1 MHz, and transmitting a mean power of P₂=1 W for a temperature rise less than Δθ=40° C., with inlet and outlet voltages V₁ and V₂ equal to 15 V (G=1). It is desired, for example, to minimize the volume of the transformer.

By selecting Q₁ as the operating point, there are obtained: a total thickness eₜₒₜ=2.3 mm; an area A=164.7 mm²; and a ratio r=0.89 (i.e. about e₁=1.1 mm and e_{2=1.2} mm). The efficiency of such a transformer is η=0.89 and the power dissipated in the transformer is 247 milliwatts (mW).

By selecting Q₂ as the operating point, solving the equations gives a ratio r greater than 6, which would give plates of very different thicknesses.

It is also possible to obtain optimum efficiency by selecting Q₀ as the operating point. This gives a total thickness eₜₒₜ=2.3 mm, an area A=1000 mm², and an efficiency of about 0.95. The resulting volume is nevertheless greater than the volume obtained for Q₁.

The material constituting the plates can be selected by implementing this method for various types of available material, e.g. as can be found in a catalog, and by selecting the material that gives the characteristics that are the most suitable for the intended application.

Because of constraints associated with fabricating the transformer (mass production, . . . ), it is naturally possible to use a transformer having dimensions that are close and providing performance that is similar to that described herein. In addition, such dimensioning can also be performed taking account of the intermediate layer 6, the properties of the means for fastening plates to a substrate, or other parameters that have been ignored in this description, should such parameters be of importance in the intended application.

Plates dimensioned in this way for a piezoelectric transformer are prepared and integrated in the printed circuit, as described above.

FIG. 5 is a diagram showing the use of an integrated piezoelectric transformer 100 for providing close drive of an electronic component 19 such as a power semiconductor component, and in particular a MOSFET or an IGBT. The primary plate 4 is connected to a primary circuit PRIM having components that are secured for example on the first layer 2 of the printed circuit (such as the electronic component 3 in FIG. 1). The secondary plate 8 is connected to a secondary circuit SEC whose components are integrated, for example, on the second layer 5 of the printed circuit (such as the electronic component 9 in FIG. 1).

In order to have adequate efficiency, the transformer 100 must be powered by an oscillator OSC at a frequency f_{R} that may be one of its resonant frequencies, for example (in particular the second mode of vibration in thickness, of the order of a few MHz, for example). In general, this frequency is not associated with the frequency of the drive signal SIG for driving the gate of the transistor to switch the transistor on and off, which frequency can be of kHz order, or about 10 kHz, for example.

A module MOD can be provided, e.g. an HEF4013 module from the supplier Philips, or the like, serving to transmit the drive signal SIG, e.g. by using full-wave modulation at the mechanical resonant frequency f_{R} of the transformer 100, which can be selected to be very much greater than the frequency of the drive signal.

The modulated signal as transmitted in this way to the integrated transformer is recovered from the secondary plate 8 and must be demodulated in order to enable a reliable close drive device to be made. The signal recovered from the secondary plate 8 is likewise at the frequency f_{R}. This signal can be rectified in conventional manner, for example, using a diode bridge 10, and demodulated using a demodulator DEM, which detects the envelope of the output signal.

Alternatively, amplitude modulation can be performed at two levels, or frequency modulation at two frequencies. Under such circumstances, the piezoelectric transformer can be powered by an alternating signal capable of taking two different frequencies. For example, modulation is obtained by a multiplier controlled by the drive signal, transmitting one or the other of two signals at neighboring frequencies, as issued by oscillators.

Appropriate demodulation of the signal transmitted by the secondary plate can consist, for example, in using a phase-locked loop (PLL) delivering a voltage proportional to the transmitted frequency, or using any other appropriate means. This alternative makes it possible to vary the duty ratio of the signal between 0 and 1. Other modulation/demodulation systems can be applied within the ambit of the invention.

At the outlet from the modulator DEM, when a switching instruction arises in the drive signal, a drive voltage of sufficient amplitude to drive the electronic power component 19 is obtained, e.g. by means of a capacitor 14 which stores the energy supplied to the secondary plate 8.

There is a transient regime of about 10 microseconds duration that corresponds to the time needed to set up stable vibration conditions in the transformer 100. This delay time t_{R} is associated with the properties of the material used (t_{R}=2e²ρ/ηπ). It is thus possible to reduce this delay time t_{R} by reducing thickness or by increasing viscosity η, which in either case increases losses in the transformer. A compromise must therefore be found between delay time and losses.

In order to overcome the problems associated with this delay time, provision can optionally be made for a locking device VER, e.g. in the form of a logic bistable whose state is to be locked for a predetermined duration after each switching instruction. This locking device enables the outlet node 11 to be provided with a rectified voltage having the amplitude needed for driving the electronic power component 19, while guaranteeing a high degree of reliability, and in particular excellent robustness in the face of electromagnetic disturbances.

It is thus possible to provide excellent isolation for a close drive signal to an electronic power component 19.

FIG. 6 shows how a complete bridge arm can be implemented, using two piezoelectric transformers 100 as described that are integrated in a printed circuit, with their primary and secondary plates being likewise as described above. For example, provision can be made for the primary plate of each transformer to be integrated on a first layer 2 of printed circuit, and for the secondary plate of each transformer and possibly the electronic power component 19 to be integrated on the second layer 5. Each transformer 100 serves to switch an electronic component 19 such as an IGBT (and the matching diode 15) in one arm of the complete bridge. By way of example, this bridge arm may present a power of 3 kW (maximum switched voltage U of 300 V for a maximum switched current I₀ of 20 amps (A)) at 40 kHz, with a duty ratio that can be varied in the range 0 to 1. The actual structure of each integrated transformer 100 provides galvanic isolation, and ensures that the system is robust in the face of any common mode currents, that might pass via the two close drives, and in particular currents associated with parasitic capacitive coupling between the primary and secondary plates of the transformers 100. This coupling can be high because the primary and secondary plates present a permittivity coefficient that is relatively high. This high permittivity nevertheless makes it possible to implement a transformer 100 presenting a high breakdown field, e.g. of the order of several kilovolts per millimeter (kV/mm).

Unlike the devices used in the prior art for achieving close drive of an insulated gate transistor, which can require non-standard coil components, the transformer used in the context of the invention is easy to industrialize.

It can also be highly miniaturized, thus leading to low fabrication costs.

1. An electronic circuit provided with a piezoelectric transformer for driving an electronic component, in which circuit the transformer comprises a primary plate and a secondary plate made from a piezoelectric material, together with an intermediate insulating layer interposed between the primary and secondary plates, the primary plate being arranged to transmit a displacement signal to the secondary plate through the intermediate layer in response to a primary signal that is transmitted to the primary plate via the electronic circuit, and the secondary plate delivering a secondary signal to the electronic component as a function of the primary signal for the purpose of driving the electronic component to which the secondary plate is connected,
the circuit being characterized by the fact that it comprises a first layer in which the primary plate is integrated and a second layer in which the secondary plate is integrated, the first and second layers being galvanically isolated from each other by the intermediate layer.

2. An electronic circuit according to claim 1, in which the first and second layers are constituted by a substrate of a material selected from printed circuit material, ceramic material, and semiconductor material, and each supporting one printed circuit face, the primary and secondary plates being fastened in recesses previously formed in each of the layers respectively.

3. An electronic circuit according to claim 2, in which at least one conductive layer is interposed between the first and second layers.

4. An electronic circuit according to claim 1, in which the electronic component is a power transistor integrated in the second layer and having a gate receiving the secondary signal.

5. An electronic circuit according to claim 1, the first layer having a primary circuit comprising a modulator connected to the primary plate and adapted to form the primary signal with at least one carrier signal being modulated by a drive signal, and to deliver the primary signal as formed in this way to the primary plate; and
the second layer having a secondary circuit comprising a demodulator connected between the secondary plate and the electronic component, and adapted to transmit to said electronic component a signal demodulated from the secondary signal corresponding to the drive signal.

6. An electronic circuit according to claim 5, in which the secondary circuit further comprises a rectifier device connected between the secondary plate and the demodulator, and adapted to rectify the secondary signal delivered by the secondary plate.

7. An electronic circuit according to claim 5, in which the secondary circuit further comprises a locking device connected between the demodulator and the electronic component and adapted to deliver a reliable demodulated signal to the electronic component.

8. An electronic circuit according to claim 5, comprising an oscillator adapted to deliver the carrier signal to the modulator at a frequency that is close to a mechanical resonant frequency of the transformer.

9. An electronic circuit according to claim 8, in which the oscillator is adapted to deliver a carrier signal at a frequency close to the frequency of the second resonant mode of vibration of the transformer.

10. An electronic circuit according to claim 1, in which the primary and secondary plates are made out of a piezoelectric material that is biased in thickneness.

11. An electronic circuit according to claim 1, in which the electronic component is a MOSFET or an IGBT.

12. An electronic circuit according to claim 1, further comprising an additional piezoelectric primary plate integrated in the first layer, and an additional piezoelectric secondary plate integrated in the second layer and connected to an additional electronic component, the electronic component being connected to form a complete arm of a bridge.
